(19) United States
(12) Patent Application Publication
(10) Pub. No.: US 2005/0287716 A1
(43) Pub. Date: Dec. 29, 2005

(54) Electronic device package

(75) Inventors: Walter L. Moden, Meridian, ID (US); Todd O. Bolken, Meridian, ID (US)

Correspondence Address: SCHWEGMAN, LUNDBERG, WOESSNER & KLUTH, 1600 TCF TOWER, 121 SOUTH EIGHT STREET, MINNEAPOLIS, MN, 55402, US

(73) Assignee: Micron Technology, Inc.

(21) Appl. No.: 11/216,965

(22) Filed: Aug. 31, 2005

Related U.S. Application Data
(62) Division of application No. 10/156,543, filed on May 28, 2002.

(51) Int. Cl. H01L 21/44

(52) U.S. Cl. 438/127; 438/126; 438/112

(57) ABSTRACT

A packaged assembly including an interposer or substrate supporting on a first side thereof a chip that is encased with an encapsulant is described. A second side of the interposer or substrate includes a barrier that blocks the flow of encapsulant to create a uniform encapsulant edge on the second side of the interposer. The uniform edge helps prevent flaking of the encapsulant off the interposer. The packaged assembly is adapted to be used with a further electronic device to expand the capablilities of the further electronic device.

This application is a Divisional of U.S. application Ser. No. 10/156,543, filed May 28, 2002, which is incorporated herein by reference.

### FIELD OF THE INVENTION

The present invention relates generally to an electronic device package, and more specifically to an overmolded electronic package.

### BACKGROUND OF THE INVENTION

In the packaging of electronic devices, such as semiconductor chip assemblies, it has been found desirable to place encapsulation material on and around elements of the semiconductor chip. Encapsulation material helps to reduce and redistribute strain, stress, and damage between the semiconductor chip and the connections made therefrom. It also reduces strain, stress, and damage between the chip and supporting substrates such as printed circuit boards. Additionally, the encapsulation material seals the components against the elements as well as facilitates continued electrical contact between the semiconductor chip and the printed circuit board. Additionally, the encapsulation material may hold the entire semiconductor chip package together.

Manufacturing machines must also be able to handle the chip package under commercial assembly conditions without damaging the chip assembly. However, if a semiconductor chip package assembly needs to be self-packaged, care must be taken during encapsulation to ensure that placement of the encapsulation material does not compromise the integrity of the terminals on the substrate such as a ball array and the like. In particular, it is important to avoid contacting the terminals on the substrate with the encapsulation material.

In the chip packaging field, miniaturization includes the process of crowding an increasing number of microelectronic circuits onto a single chip and simultaneously reducing the overall chip package size so as to achieve smaller and more compact devices. Examples of such devices include hand-held computers, personal data assistants, portable telecommunication devices, portable music devices such as tape players, CD players, digital music players, and the like. It is desirable to economically produce such devices at a smaller and smaller size yet increase the capability of such devices.

One type of encapsulation is overmolding. Overmolding technology includes assembling the chip on a frame. The chip assembly is then positioned in a mold and the final package configuration is defined by plastic molding around the chip assembly. Since the lead frame assembly is relatively flexible, the position of the die with respect to the overmolded portion of the package is not necessarily fixed. The overmolding or encapsulant protects and insulates not only the intervening die or chip but the lead frame and the wire bonding wires as well. With a chip assembly in a mold, the encapsulant is injected into the mold and air is exhausted from the opposite end of the mold. In some applications of overmolding it is desirable to encapsulate the sides of the chip and the frame or substrate. However, such molding results in a non-uniform edge of the encapsulant which results in a tendency for the encapsulant to flake at the edges. Flaking may result in the encapsulant inadequately protecting the chip and/or connections. Moreover, such flaking gives the overmolded assembly an unfinished appearance or may result in delamination of the encapsulant from the package.

FIG. 7 shows a view of a conventionally overmolded package 700. The encapsulant 701 is on a substrate 702. The encapsulant 701 has various bleed over areas 703 that contribute to the problems stated above.

### SUMMARY OF THE INVENTION

The above mentioned problems with packages and devices including such packages, and other problems are addressed by the present invention and will be understood by reading and studying the following specification.

An embodiment of the invention includes an assembly that has an interposer, an electrical device connected to the interposer, a covering encasing the electrical device, and a barrier impeding the flow of the covering on the interposer. In an embodiment, the barrier is positioned at or greater than 0.1 mm from an edge of the interposer. In an embodiment, the barrier is positioned at or less than 0.4 mm from an edge of the interposer. In an embodiment, the covering extends less than or equal to about 0.4 mm inwardly from the edge of the interposer on its second side. In an embodiment, the covering extends greater than or equal to about 0.1 mm inwardly from the edge of the interposer on its second side. In an embodiment, the barrier extends outwardly from the surface of the interposer.

An embodiment of the present invention includes an assembly that has an interposer having a first side, a second side, and an edge extending between the first side and the second side. An electrical device is connected to the first side of the interposer. A covering encases the electrical device and extends around the edge onto the second side. The covering has a substantially linear edge on the second side. In an embodiment, a barrier extends outwardly from the second side of the interposer to impede the covering from bleeding past the barrier on the second side. In an embodiment, the covering has a flowable state and a non-flowable state. In an embodiment, the covering is the outer case for a portable device.

A further embodiment of the invention is a method for forming a package. In an embodiment, the method controls bleeding of a covering on a substrate.

Further features and advantages of the present invention, as well as the structure and operation of various embodiments of the present invention, are described in detail below with reference to the accompanying drawings.

### BRIEF DESCRIPTIONS OF THE DRAWINGS

The present invention is described with reference to the accompanying drawings. In the drawings, like reference numbers indicate identical or functionally similar elements.

FIG. 1 is a bottom plan view of a package according to the present invention.

FIG. 2 is a partial, cross-sectional view taken generally along line 2-2 in FIG. 1.

FIG. 3 is a partial cross sectional view of a mold for producing a package according to the present invention.

FIG. 4 is a flow chart of a process according to the present invention.

FIG. 5 is a view of a portable electronic device including a package according to the present invention.

FIG. 6 is a partial micrograph of the package according to the present invention.

FIG. 7 is a partial micrograph of a conventional package.

Certain terminology will be used in the following description for convenience in reference only, and will not be limiting. For example, the words “up”, “down”, “right”, and “left” will refer to directions in the drawings to which reference is made. The words “inwardly” and “outwardly” will refer to directions toward and away from, respectively, the geometric center of the system and designated parts thereof. The terminology will include the words specifically mentioned, derivatives thereof, and words of similar meaning.

### DETAILED DESCRIPTION OF THE EMBODIMENTS

In the following detailed description of various embodiments of the present invention, reference is made to the accompanying drawings which form a part hereof, and in which is shown by way of illustration specific embodiments in which the invention may be practiced. These embodiments are described in sufficient detail to enable those skilled in the art to practice the invention, and it is to be understood that other embodiments may be utilized and that logical, mechanical and electrical changes may be made without departing from the spirit and scope of the present invention. The following detailed description is, therefore, not to be taken in a limiting sense, and the scope of the present invention is defined by the appended claims and their equivalents.

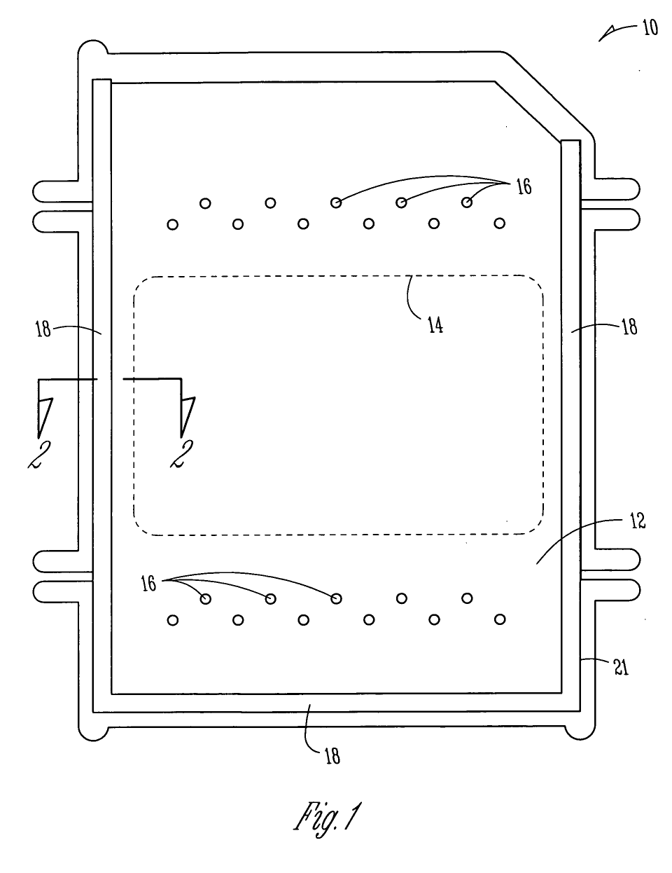

FIG. 1 shows a bottom view of a packaged assembly 10 including an interposer 12 and an integrated circuit chip 14 connected to one side, e.g., top surface, of the interposer 12. The interposer 12 is, in an embodiment, a printed circuit board including a plurality of contacts (not shown) that electrically and mechanically connect to contacts (not shown) on the chip 14. Interposer 12 is a substrate or frame for the chip 14 that supports the chip and provides contacts 16 to external circuits. Traces (not shown) connect the contacts 16 to the chip 14. The chip 14 connects to the interposer 12 by an adhesive or glue. In an embodiment, the chip 14 is soldered to the interposer. The types of chips 14 include flip chip or wire bonded chip.

The chip 14 includes integrated circuits capable of performing at least one of memory functions, logic functions, and processing functions. In an embodiment, the chip 14 includes a memory device such as a DRAM (Dynamic Random Access Memory), SRAM (Static Random Access Memory) or Flash memories. Additionally, the DRAM could be a synchronous memory device such as SGRAM (Synchronous Graphics Random Access Memory), SDRAM (Synchronous Dynamic Random Access Memory), SDRAM II, and DDR SDRAM (Double Data Rate SDRAM), as well as Synchlink or Rambus DRAMs and other emerging memory technologies. In an embodiment, the chip 14 includes a microprocessor. In an embodiment, chip 14 includes a logic array. The chip 14, in an embodiment, is part of a circuit module. The circuit module is part of at least one of memory modules, device drivers, power modules, communication modems, processor modules and application-specific modules, and may include multilayer, multichip modules. The chip 14 as part of the circuit module or alone may be a subcomponent of a variety of electronic systems, such as a control system, a printer, a scanner, a clock, a television, a cell phone, a personal computer, personal data assistant, an automobile, an industrial control system, an aircraft, an automated teller machine and others. The chip 14, in an embodiment, is adapted to be removably connectable to the circuit module such that the chip 14 expands the function of the circuit module, e.g., expand memory or add additional logic processes.

A barrier 18 is positioned on a bottom surface 19 of the interposer 12. The barrier 18 extends outwardly from the interposer bottom surface 19. The barrier 18 has a height generally equal to the thickness of the interposer in an embodiment. In an embodiment, barrier 18 has a height less than the thickness of the interposer 12. In an embodiment, the barrier 18 is a soldermask that is patterned on the interposer bottom surface along each edge where the encapsulant folds over the interposer edge as explained herein. Barrier 18 extends above, i.e., is cantilevered from, the interposer bottom surface. The barrier 18 has a well-defined, substantially linear outer surface 21 that extends transversely to the interposer bottom surface. In an embodiment, the outer surface 21 is substantially perpendicular to the interposer bottom surface. In an embodiment, the barrier 18 is an upraised portion of the interposer. In an embodiment, the barrier is an epoxy, glass or other construction that is formed on the interposer to impede flow of an encapsulant. The barrier outer surface 21 is spaced inwardly from the outer edge of the interposer about 0.4 mm. In an embodiment, the barrier outer surface 21 is spaced inwardly from the interposer outer edge less than about 0.4 mm. In an embodiment, the barrier outer surface 21 is spaced inwardly from the interposer outer edge about 0.2 mm. In an embodiment, the barrier outer surface 21 is spaced inwardly from the interposer outer edge about 0.1 mm. In an embodiment, the barrier outer surface 21 is spaced inwardly from the interposer outer edge greater than about 0.1 mm.

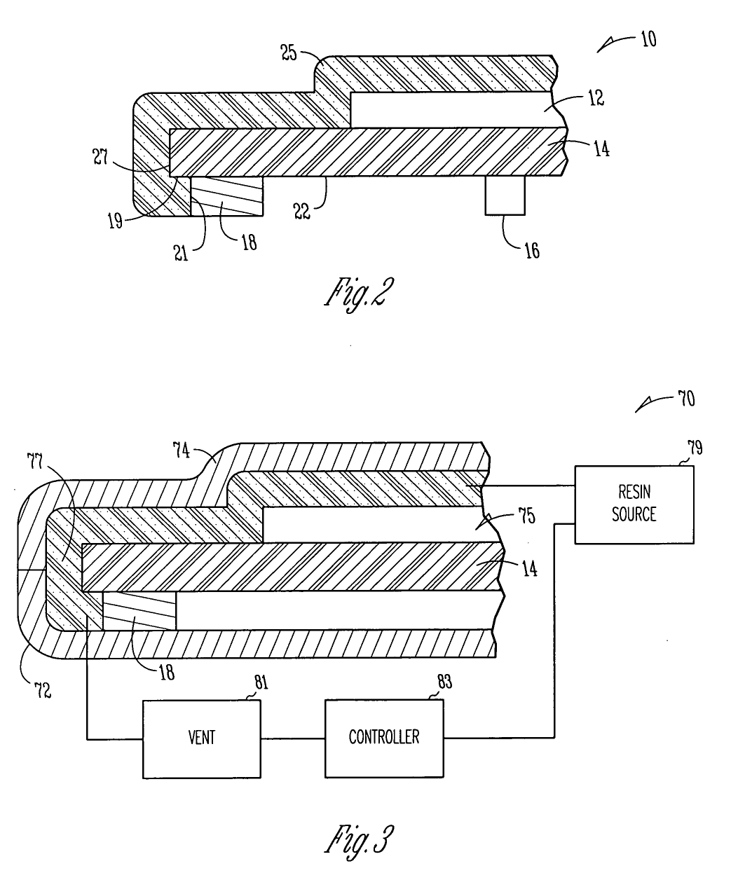

FIG. 2 shows a partial, cross-sectional view of the FIG. 1 packaged assembly. An electronic device, e.g., chip 14, is fixed to a first (top as shown in FIG. 2) surface of the interposer 12. The barrier 18 extends outwardly (downwardly as shown in FIG. 2) from a second surface 19 of the interposer 12. Thus, the barrier 18 creates an inner recess 22 with the interposer, wherein the contacts 16 are positioned. An encapsulant 25 covers the chip 14. In an embodiment, encapsulant 25 completely covers the chip 14 and the first surface of the interposer 12. The encapsulant 25 extends around the edge 27 of the interposer and onto the second surface 19 of the interposer 12. The encapsulant 25 abuts the barrier 18. In an embodiment, the encapsulant 25 has substantially the same height as the barrier 18. The barrier 18, thus, prevents the encapsulant 25 from bleeding further inwardly on the second surface of the interposer and keeps the inner recess 22 free from the encapsulant. Thus, the encapsulant 25 ends on the interposer second surface in a generally linear edge. Moreover, the encapsulant 25 on the interposer second surface tends to have a consistent depth. The linear edge and consistent depth give the encapsulant a finished appearance and, furthermore, reduce the tendency of the encapsulant to flake at the edge. The encapsulant 25 protects the chip 14 and the portion of the interposer 12 covered by the encapsulant from the environment, e.g., moisture, dirt, debris, etc. Encapsulant 25 further provides mechanical support to the assembly 10. Encapsulant 25 also protects the chip 14 and interposer 12 from direct physical contact.

FIG. 3 shows an embodiment of a system 70 for producing a package according to the present invention. System 70 includes a top and bottom mold 72, 74 that enclose the interposer, chip assembly 75. The assembly 75 includes the interposer 12, chip 14 and barrier 18 as described herein. The molds 72, 74 effectively seal the interposer, chip assembly 75 while creating a chamber 77 that receives the encapsulant material. The chamber 77 is bound where the barrier 18 contacts the top mold 72. System 70 includes an encapsulant material source 79 fluidly connected to the cavity. Source 79 injects encapsulant material into chamber 77 to completely cover chip 14 and extend around the edge of the interposer until the encapsulant material contacts barrier 18. In an embodiment, the encapsulant material is flowable during injection. Thereafter, the material cures into a hardened, non-flowable state. The barrier 18 prevents the encapsulant material from flowing outside the chamber 77 toward the surface of the interposer that includes the contacts for external connection. In an embodiment, the system 70 includes a vent 81 connected to the chamber 77. The vent 81 discharges gas from the cavity 77 during injection of the encapsulant material, which assists in encapsulant flow and a uniform encapsulation coverage of the assembly 75. A controller 83 is provided to control operation of the molds 72, 74, the encapsulant source 79, and vent 81.

The encapsulant material is chosen according to the requirements of the fabrication procedure and the specifications of the finished product. In an embodiment the encapsulant material is a curable resin. One example of a curable resin is PRS 4000, AUS-8 by Taiyo Yuden Corp.

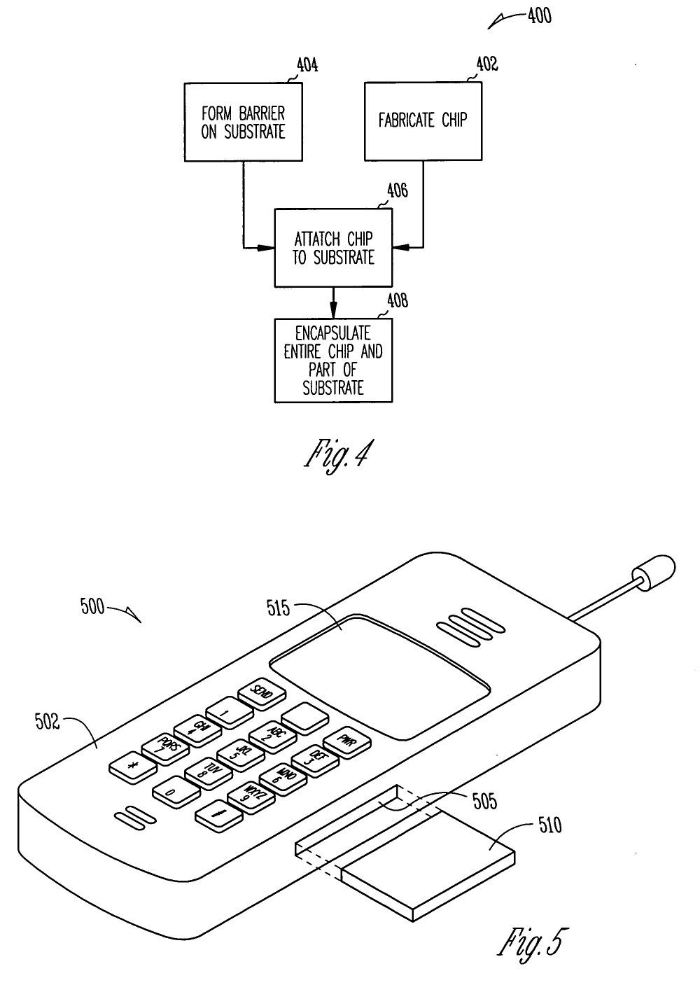

FIG. 4 shows a method 400 for producing a package according to the present invention. A chip 14 is fabricated according to techniques know to those in chip fabrication arts according to the intended use of the chip (step 402). A barrier 18 is formed on the substrate 12 (step 404). The barrier 18 is positioned on one side of the substrate, which substrate side includes connections adapted to connect to circuits external to the chip and substrate. Barrier 18 is positioned more than or equal to 0.1 millimeter and less than or equal to 0.4 millimeter from the edge of the substrate. The chip 14 is electrically and physically attached to the substrate 12 on a side opposite the barrier 18 (step 406). Attaching the chip 14 includes at least one of wire bonding, flip chip connecting, gluing or other attachment techniques. In an embodiment, the barrier 18 is formed after the chip 14 is attached to the substrate 12. In an embodiment, the barrier 18 is formed before the chip 14 is attached to the substrate 12. The encapsulant then covers the chip 14 and extends over the edges of the substrate 12 into contact with the barrier 18 (step 408).

A brief description of various embodiments of structures, devices and systems in which the present invention may be incorporated follows. It will be recognized that the following are exemplary and are not exclusive of other structure, device, and systems in which the encapsulated device according to present invention may be used.

FIG. 5 shows an electronic device 500 having a housing 502 and an expansion slot 505 that opens through the housing for access to the slot from outside the housing. A media card 510 according to the teachings of the present invention is adapted to be removably mounted in the slot 505. The interface 515 connects to internal circuits (not shown) in the device 500. The slot 505 includes contacts that connect the card 510 to the internal circuits. The card 510 thus can supply expanded or new functions to the device 500 that are not provided by the internal circuits alone. For example, the card 510 is a memory device that expands the memory of device 500. The covering of the card 510, in an embodiment, is visible to the user of the device 500 at least when the card 510 is removed from the device. In an embodiment, the covering of the card 510 is also at least partly visible when the card is mounted in slot 505. In another embodiment, the card 510 is not visible when mounted in slot 505. The card 510 is releasably mounted in the slot 505 so that the card 510 is removable and is insertable into a further device or replaced by a different card that has the features of the present invention.

The electronic device 500 in an embodiment is a mobile communication device such a mobile telephone, pager, or radio. The electronic device includes at least one user interface 515 for interacting with a user. The interface 515, in an embodiment, includes at least one button for activation by the user. In the specific mobile phone application of the present invention, the user interface includes a keypad representing numeric and/or alphabetic characters. The user interface 515 for a mobile telephone further includes a speaker and a microphone.

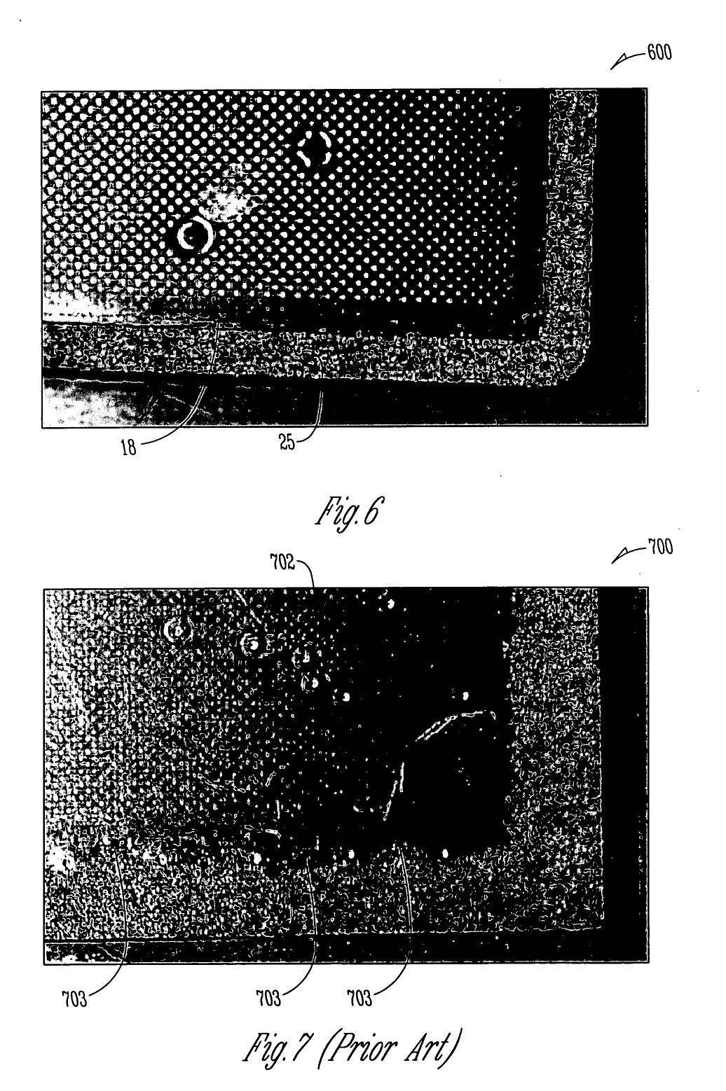

FIG. 6 shows a micrograph 600 of an encapsulated substrate according to the teachings of the present invention. A barrier 18 is formed on the side of the substrate. The encapsulant 25 extends around the edge of the substrate from the side not shown in FIG. 6 and onto the visible side of the substrate. The encapsulant 25 abuts the barrier 18 and ends in a clean, essentially linear—especially to the human eye—edge. As compared to the conventional structure shown in FIG. 7, the encapsulated substrate according to the teachings of the present invention has a more linear edge formed by the encapsulant.

### CONCLUSION

The present invention includes forming an area where the covering can consistently gather in an over-molded electronic device package. This provides a consistent covering border by limiting the covering bleed against the barrier. A non-uniform covering edge results in a visual defect whether or not such a non-uniform edge is a structural defect. The invention provides a more finished electronic device package. The present invention further assists in preventing flaking of the covering, which is undesirable as flaking may result in failure of the covering such as exposure of the chip or other covered components.

As recognized by those skilled in the art, circuit modules, such as memory devices, of the type described herein are generally fabricated as an integrated circuit containing a variety of semiconductor devices and connected to an interposer. The integrated circuit is supported by a substrate. Integrated circuits are typically repeated multiple times on each substrate. The substrate is further processed to separate the integrated circuits into dies as is known in the art. At least one die is attached to the interposer and encapsulated according to the teachings of the present invention.

1. A process for encapsulating integrated circuits on an interposer, comprising:
defining an encapsulation chamber about an integrated circuit die and an interposer;
filling the chamber with an encapsulant; and
controlling outflow of the encapsulant from the chamber by providing an upstanding barrier proximate to an edge of the interposer.

2. The method of claim 1, wherein defining an encapsulation chamber includes forming the barrier on the interposer before attaching the integrated circuit die to the interposer.

3. The method of claim 1, wherein defining an encapsulation chamber includes forming the barrier by patterning a soldermask on the interposer.

4. The method of claim 1, wherein patterning a soldermask on the interposer includes forming a soldermask barrier inwardly spaced from an edge of the interposer in a range of about 0.1 mm to about 0.4 mm.

5. The method of claim 1, wherein filling the chamber with the encapsulant includes injecting a curable resin into the chamber.

6. A method, comprising:
connecting an electrical device connected to a first side of an interposer;
encapsulating the electrical device; and
stopping bleeding of an encapsulant on a second side of the interposer to create an inner recess on the second side that is free of the encapsulant.

7. The method of claim 6, wherein encapsulating includes depositing a resin.

8. The method of claim 7, wherein encapsulating includes hardening the resin to a non-flowable state.

9. The method of claim 6, wherein connecting includes connecting the interposer to a printed circuit board.

10. The method of claim 6, wherein stopping bleeding includes stopping bleeding at a barrier is inwardly spaced from a peripheral edge of the interposer at a range of about 0.1 mm to about 0.4 mm.

11. The method of claim 6, wherein connecting includes connecting a memory device to the interposer.

12. The method of claim 11, wherein the memory device is a DRAM.

13. The method of claim 6, wherein stopping the bleeding includes forming a substantially linear edge of the encapsulant on the second side.

14. The method of claim 13, wherein encapsulating includes completely covering the first side of the interposer.

15. The method of claim 14, wherein encapsulating includes completely covering the edge of the interposer.

16. A method for forming an overmolded package, comprising:
an electrical device connected to a first side of a substrate that further includes a second side and an edge extending between the first side and the second side;
encasing the electrical device with an electrically insulating covering that extending over the edge onto the second side; and
containing bleeding of the covering on the second side creating an inner recess free from the covering.

17. The method of claim 16, wherein containing includes forming the covering to have a uniform edge on the second side.

18. The method of claim 16, wherein containing includes abutting the covering against a barrier.

19. The method of claim 16, wherein containing includes stopping the covering less than about 0.4 mm inwardly from the edge of the substrate on the second side.

20. The method of claim 16, wherein the covering extends at least about 0.1 mm inwardly from the edge of the substrate on the second side.

21. The method of claim 16, wherein the covering completely covers the first side and the edge of the substrate.

22. A method for forming an overmolded package, comprising:
an electrical device connected to a first side of a substrate that further includes a second side and an edge extending between the first side and the second side;
injecting a resin to encase the electrical device with an electrically insulating covering that extending over the edge onto the second side; and
containing bleeding of the covering on the second side creating an inner recess free from the covering.

23. The method of claim 22, wherein containing includes forming the covering to have a uniform edge on the second side.

24. The method of claim 22, wherein containing includes abutting the covering against a barrier.

25. The method of claim 22, wherein containing includes stopping the covering less than about 0.4 mm inwardly from the edge of the substrate on the second side.

26. The method of claim 22, wherein the covering extends at least about 0.1 mm inwardly from the edge of the substrate on the second side.

27. The method of claim 22, wherein the covering completely covers the first side and the edge of the substrate.

28. A method, comprising:
a substrate including a first side, a second side, and an edge extending between the first side and the second side;
connecting an electrical device connected to a first side of a substrate that further includes a second side and an edge extending between the first side and the second side;
forming a soldermask on the second side to create an inner recess; and
encapsulating the electrical device with the encapsulant abutting the soldermask.

29. The method of claim 28, wherein forming the soldermask includes inwardly spacing the soldermask from the edge about 0.1 mm.

30. The method of claim 28, wherein forming the soldermask includes inwardly spacing from the edge about 0.4 mm.

31. The method of claim 28, wherein encapsulating includes injecting a resin to encase the electrical device with an electrically insulating covering that extending over the edge onto the second side.

32. The method of claim 28, wherein forming the soldermask includes forming an opening whereat the encapsulant does not abut the soldermask.

33. The method of claim 28, wherein the soldermask impedes bleeding of the covering onto the second side.

34. The method of claim 28, wherein the inner recess separates the barrier from each of a plurality of contacts operably connected to the electrical device.
